(19) United States
(12) Patent Application Publication
(10) Pub. No.: US 2013/0202866 A1
(43) Pub. Date: Aug. 8, 2013

(54) MECHANICALLY STABLE NANOPARTICLE THIN FILM COATINGS AND METHODS OF PRODUCING THE SAME

(71) Applicant: Daeyeon Lee, Wynnewood, PA (US)

(72) Inventor: Daeyeon Lee, Wynnewood, PA (US)

(73) Assignee: THE TRUSTEES OF THE UNIVERSITY OF PENNSYLVANIA, Philadelphia, PA (US)

(21) Appl. No.: 13/877,005

(22) PCT Filed: Sep. 23, 2011
(86) PCT No.: PCT/US2011/052920

§ 371 Date: Mar. 29, 2013

Related U.S. Application Data
(60) Provisional application No. 61/388,323, filed on Sep. 30, 2010.

(51) Int. Cl. C23C 16/44; C23C 16/513; C23C 16/56

(52) U.S. Cl. CPC C23C 16/44; C23C 16/56; C23C 16/513
USPC 428/216; 427/203; 427/535; 427/576; 428/322.7

(57) ABSTRACT

A method for treating a surface comprises depositing a first coating comprising a plurality of nanoparticles on a substrate, wherein the first coating defines a plurality of interstitial spaces; and depositing a second coating comprising metals, metal oxides, or mixtures thereof by atomic layer deposition (ALD) on the first coating and within the interstitial spaces defined by the first coating. A mechanically stable coated product comprises a substrate; a first coating comprising a plurality of nanoparticles deposited on the substrate; wherein the first coating defines a plurality of interstitial spaces; and a second coating comprising metals, metal oxides, or mixtures thereof deposited by atomic layer deposition (ALD) on the first coating and within the interstitial spaces defined by the first coating. The mechanically stable thin film coating imparts mechanical robustness to the nanoparticles thin film, and retains or improves the desired optical and wetting properties of the nanoparticle thin film.

### CROSS-REFERENCE TO RELATED APPLICATIONS

This application claims priority to U.S. Patent Application No. 61/388,323, entitled “MECHANICALLY STABLE NANOPARTICLE THIN FILM COATINGS AND METHODS OF PRODUCING THE SAME,” filed on Sep. 30, 2010, the contents of which are incorporated herein by reference in their entirety.

### FIELD OF THE INVENTION

This invention relates to superhydrophilic coatings. Specifically, this invention relates to superhydrophilic mechanically stable nanoparticle thin film coatings which may have additional functions. This invention also relates to methods of producing such coatings on substrates.

### BACKGROUND OF THE INVENTION

Transparent surfaces become fogged when tiny water droplets condense on the surface, thereby scattering light and often rendering the surface translucent. Fogging frequently occurs when a cold surface suddenly comes in contact with warm, moist air. Fogging severity can ultimately compromise the usefulness of the transparent material. In some cases, fogging can be a dangerous condition, for example when the fogged material is a vehicle windscreen or goggle lens. Current commodity anti-fog coatings often lose effectiveness after repeated cleanings over time, and therefore require constant reapplication to ensure their effectiveness.

Coatings can be formed on substrates by, for example, layer-by-layer assembly of films including nanoparticles, polyelectrolytes, or a combination of these. These coatings can impart desired optical and wetting properties on the substrate, such as antifogging, antireflective, and self-cleaning characteristics. These coatings can have high transparency, high anti-fog efficiency, long environmental stability, high scratch and abrasion resistance, and high mechanical integrity. Preferably, a single coating has a combination of these properties, such as the coating taught by U.S. Patent Application Publication No. 2008/0268229, incorporated herein by reference.

In addition to the optical and wetting properties, mechanical integrity (e.g., durability and adhesion) of a coating can be important in practical applications. Known methods for improving the mechanical stability of a coating focus on the use of interpenetrating charged macromolecules, which bridge deposited materials together within the coatings, and/or the use of a calcination process whereby the coating and substrate are treated at a high temperature (e.g., 550° C.) for a period of time sufficient to fuse deposited materials, such as nanoparticles, together. See, e.g., U.S. Patent Application Publication No. 2007/0104922, which is incorporated herein by reference in its entirety. Such thermal treatment, however, is not amenable to substrates, such as plastics or polymer substrates, which tend to deform and degrade at high temperatures. Additionally, hydrothermal treatment at relatively low temperatures (124-134° C.) has been employed to improve the mechanical durability of nanoporous all-nanoparticle and polymer-nanoparticle layer-by-layer (LbL) films on both glass and polycarbonate substrates (see, e.g., Gemici, Z.; Shimomura, H.; Cohen, R. E.; Rubner, M. F. Langmuir 2008, 24, 2168-2177, and U.S. Patent Application Publication No. 2008/0038458, each of which is incorporated herein by reference in its entirety). The nanoparticle coatings, however, have been found to lose some of their desirable characteristics, such as anti-fogging properties, as a result of hydrothermal treatment.

### SUMMARY OF THE INVENTION

It has now been discovered that mechanically stable thin film coatings can be formed by atomic layer deposition (ALD) of a coating on top of, and within the interstitial void spaces defined by, an as-assembled film coating on a substrate. The as-assembled film coating can be formed by a myriad of methods, for example by layer-by-layer (LbL) deposition of nanoparticles. These thin film coatings impart desired optical and wetting properties on the substrate, such as antifogging, antireflective, and self-cleaning characteristics. Additionally, the thin film coatings provide mechanical integrity, such as high scratch and abrasion resistance, to the as-assembled film coating and the substrate.

The mechanically stable thin film coatings are suitable for low temperature heat treatment, to further improve the mechanical integrity of the coatings, which make them ideal for substrates that are unable to be treated at high temperatures, such as plastics. The coatings of the present invention impart desired optical and mechanical properties to the underlying coatings and substrates, without adding substantially to the thickness of the thin film coating.

The coatings can be used in any application where the condensation of water droplets on a surface is undesired, particularly where the surface is a transparent surface or a reflective surface. Examples of such applications include sport goggles, auto windshields, windows in public transit vehicles, windows in armored cars for law enforcement and VIP protection, photovoltaic cells and solar panels, green-house enclosures, Sun-Wind-Dust goggles, laser safety eye protective spectacles, chemical/biological protective face masks, ballistic shields for explosive ordnance disposal personnel, mirrors, and vision blocks for light tactical vehicles, among others.

In one embodiment, the present invention is a method for treating a surface, the method comprising: depositing a first coating comprising a plurality of nanoparticles on a substrate, wherein the first coating defines a plurality of interstitial spaces; and depositing a second coating comprising metals, metal oxides, or mixtures thereof by atomic layer deposition (ALD) on the first coating and within the interstitial spaces defined by the first coating. The first coating may include a plurality of nanoparticles and a polymer in the form of a film. The second coating may impart specific functionality to the thin film coating, or one or more functional coatings may be deposited by atomic layer deposition after deposition of the second coating. Such functional coatings may contain elements which impart specific functionality such as, for example, catalytic, optical, absorptive, semiconducting, abrasion-resistive, or corrosion-resistive functionality to the functional coatings.

In one or more embodiments of the present invention, the method of treating a surface may further include, after or during the step of depositing the second coating, the step of treating by plasma treatment or ozone treatment. Alternatively, or additionally, the method of treating a surface may further include, after the step of depositing the second coating, the step of heating the substrate to a temperature of about 100° C. to about 300° C. The first coating may be deposited on the substrate by a myriad of methods known to one having ordinary skill in the art such as, for example, spin-coating, Is dip-coating, solution-coating, doctor blading, or spray-coating. The first coating may include, for example, silicon dioxide nanoparticles, titanium dioxide nanoparticles, and mixtures thereof. Suitable metal oxides for the second coating include, for example, aluminum oxide (Al₂O₃), silicon oxide (SiO₂), and titanium oxide (TiO₂), and mixtures thereof.

In another embodiment, the present invention is a process for producing a mechanically stable coating on a surface. The process comprises the steps of: depositing an adhesion layer comprising metals, metal oxides, or mixtures thereof by atomic layer deposition (ALD) on a substrate; depositing a first coating comprising a plurality of nanoparticles on the adhesion layer, wherein the first coating defines a plurality of interstitial spaces; and depositing a second coating comprising metals, metal oxides, or mixtures thereof by atomic layer deposition (ALD) on the first coating and within the interstitial spaces defined by the first coating.

In yet another embodiment, the present invention is a mechanically stable coated product. The mechanically stable coated product comprises a substrate; a first coating comprising a plurality of nanoparticles deposited on the substrate, wherein the first coating defines a plurality of interstitial spaces; and a second coating comprising metals, metal oxides, or mixtures thereof deposited by atomic layer deposition (ALD) on the first coating and within the interstitial spaces defined by the first coating. The second coating of the mechanically stable thin film coating may impart specific functionality to the thin film coating. Alternatively, or additionally, the mechanically stable thin film coating may include one or more additional functional coatings deposited by atomic layer deposition. The second coating is deposited at a thickness of about 0.01 nanometers to about 100 nanometers. Because the second coating is applied over, and within the interstitial void spaces, of the first coating, the total thickness of the mechanically stable thin film coating is mostly dependent on the thickness of the first coating. In general, the total thickness of the mechanically stable thin film coating may be from about 0.01 nanometers to about 100 microns. As is known to one having ordinary skill in the art, the total coating thickness depends on the particular use and the substrate on which the coating is applied.

The details of one or more embodiments are set forth in the accompanying drawings and the description below. Other features, objects, and advantages will be apparent from the description and drawings, and from the claims.

### BRIEF DESCRIPTION OF THE FIGURES

FIGS. 1(a)-1(d) diagram a mechanically stable nanoparticle thin film coating, according to one embodiment of the present invention, as it is applied to a substrate;

FIGS. 2(a)-2(b) detail the film thickness and refractive index, respectively, as measured by spectroscopic ellipsometry for one embodiment of the present invention;

FIG. 3 shows the change in volume fraction by application of the mechanically stable thin film coating, according to one embodiment of the present invention;

FIGS. 4(a) and 4(b) show the UV/Visible spectrophotometry results and water contact angle measurements for the mechanically stable thin film coating, according to one embodiment of the present invention;

FIGS. 5(a) and 5(b) show the UV/Visible spectrophotometry results and water contact angle measurements for the mechanically stable thin film coating, according to another embodiment of the present invention;

FIGS. 6(a)-6(d) present the transmission levels measured by UV/Visible spectrophotometry for various coatings applied to glass substrates;

FIGS. 7(a) and 7(b) provide Scanning Electron Microscope images of a five bilayer as-assembled TiO₂/SiO₂ nanoparticle thin film coating deposited on a glass substrate, before and after abrasion testing, respectively;

FIGS. 8(a) and 8(b) provide Scanning Electron Microscope images of a five bilayer as-assembled TiO₂/SiO₂ nanoparticle thin film coating deposited on a glass substrate, modified by 10 cycles of a stabilization coating deposited by atomic layer deposition, before and after abrasion testing, respectively. The images in 8(b) are shown at varying magnification;

FIGS. 9(a) and 9(b) present the hardness measurements, by nanoindentation testing, charting displacement h in nanometers (nm) and hardness H in gigapascals (GPa). Displacement of the samples is shown from 0 to 620 nm in FIG. 9(a), while FIG. 9(b) shows a magnified view for the displacement range between 0 to 150 nm;

FIGS. 10(a) and 10(b) present the calculated modulus measurements in graphical form. Displacement of the samples is shown from 0 to 620 nm in FIG. 10(a), while FIG. 10(b) shows a magnified view for the displacement range between 0 to 150 nm.

### DETAILED DESCRIPTION OF THE INVENTION

Surfaces having a nanotexture can exhibit extreme wetting properties. A nanotexture refers to surface features, such as ridges, valleys, or pores, having dimensions on the nanometer scale (i.e., typically less than 1 micrometer). In some cases, the features will have an average or root mean square (rms) dimension on the nanometer scale, even though some individual features may exceed 1 micrometer in size. The nanotexture can be a 3D network of interconnected pores. Depending on the structure and chemical composition of a surface, the surface can be hydrophilic, hydrophobic, or at the extremes, superhydrophilic or superhydrophobic.

As is well known in the art, hydrophilic surfaces attract water while hydrophobic surfaces repel water. In general, a non-hydrophobic surface can be made hydrophobic by coating the surface with a hydrophobic material. The wetting properties of a surface can be measured, for example, by determining the contact angle of a drop of water on the surface, which can be a static contact angle or dynamic contact angle. A dynamic contact angle measurement can include determining an advancing contact angle or a receding contact angle, or both. A superhydrophilic surface is completely and instantaneously wet by water, i.e., exhibiting water droplet advancing contact angles of less than 5 degrees within 0.5 seconds or less upon contact with water. See, for example, Bico, 3. et al., Europhys. Lett. 2001, 55, 214-220, which is incorporated by reference in its entirety.

One method to create the desired surface coating texture and wetting properties is by layer-by-layer (LbL) deposition. Layer-by-layer deposition may be utilized to deposit an as-assembled film coating on a substrate. For example, U.S. Patent Application Publication No. 2008/0268229, incorporated herein by reference, describes layer-by-layer deposition of an as-assembled polyelectrolyte multilayer coating. Layer-by-layer processing of polyelectrolyte multilayers can be used to make conformal thin film coatings with molecular level control over film thickness and chemistry. Charged polyelectrolytes can be assembled in a layer-by-layer fashion. In other words, a polyelectrolyte is a material bearing more than a single electrostatic charge, i.e. positively- and negatively-charged polyelectrolytes, which can be alternately deposited on a substrate. One method of depositing the polyelectrolytes is to contact the substrate with an aqueous solution of polyelectrolyte at an appropriate pH. The pH can be chosen such that the polyelectrolyte is partially or weakly charged. The multilayer can be described by the number of bilayers it includes, a bilayer resulting from the sequential application of oppositely charged polyelectrolytes.

As-assembled multilayer thin films containing nanoparticles of SiO₂ can also be prepared via layer-by-layer assembly (see Lvov, Y.; Ariga, K.; Onda, M.; Ichinose, I.; Kunitake, T. Langmuir 1997, 13, (23), 6195-6203, which is incorporated by reference in its entirety). Other studies describe multilayer assembly of Ti0₂ nanoparticles, SiO₂ sol particles and single or double layer nanoparticle-based anti-reflection coatings. See, for example, Zhang, X-T.; et al. Chem. Mater. 2005, 17, 696; Rouse, 3. H.; Ferguson, G. S. J. Am. Chem. Soc. 2003, 125, 15529; Sennerfors, T.; et al. Langmuir 2002, 18, 6410; Bogdanvic, G.; et al. J. Colloids Interface Science 2002, 255, 44; Hattori, H. Adv. Mater. 2001, 13, 51; Koo, H. Y.; et al. Adv. Mater. 2004, 16, 274; and Ahn, J. S.; Hammond, P. T.; Rubner, M. F.; Lee, I. Colloids and Surfaces A: Physicochem. Eng. Aspects 2005, 259, 45, each of which is incorporated by reference in its entirety. Incorporation of TiO₂ nanoparticles into a multilayer thin film can improve the stability of the superhydrophilic state induced by light activation. See, e.g., Kommireddy, D. S.; et al. J. Nanosci. Nanotechnol. 2005, 5, 1081, which is incorporated by reference in its entirety.

The as-assembled multilayer coating can include a plurality of nanoparticles to provide a nanometer-scale texture or roughness to the surface. The nanometer-scale texture can be used to increase the surface area of the substrate and/or the as-assembled multilayer coating. The nanoparticles can be nanospheres such as, for example, silica nanospheres, titania nanospheres, polymer nanospheres (such as polystyrene nanospheres), or metallic nanospheres. The nanoparticles can be metallic nanoparticles, such as gold or silver nanoparticles. The nanoparticles can also be other well known nano-scale materials such as, for example, nanotubes, nanoribbons, nanocrystals, quantum dots, graphene, and fullerenes. The nanoparticles can have diameters of, for example, between 1 and 1000 nanometers, between 10 and 500 nanometers, between 20 and 100 nanometers, or between 1 and 100 nanometers. The intrinsically high wettability of nanoparticles and the rough and porous nature of the multilayer surface establish favorable conditions for extreme wetting behavior.

Alternatively, the as-assembled multilayer coating may be comprised, at least in part, of nanoparticles. For example, the multilayer can include a polyelectrolyte and a plurality of hydrophilic nanoparticles. By choosing appropriate assembly conditions, a 3D nanoporous network of controllable thickness can be created with the nanoparticles. The network can be interconnected—in other words, the nanopores can form a plurality of connected interstitial voids. Rapid infiltration (nano-wicking) of water into this network can drive the superhydrophilic behavior.

The as-assembled coatings can be made by, for example, a layer-by-layer deposition process, in which a substrate is contacted sequentially with an aqueous solution. The substrate can be contacted with the aqueous solution by, for example, immersion, printing, spin-coating, dip-coating, solution-coating, doctor blading, spray-coating, Langmuir-Blodgett method, or other methods, as is known to one having ordinary skill in the art. The as-assembled multilayer coating can be applied in a single step or in a multi-step process. For example, when the as-assembled coating includes a polymer and a plurality of nanoparticles, it can be applied to the substrate in a single step as a mixed polymer and nanoparticles solution. Alternatively, the polymer layers and nanoparticle layers can be deposited in an alternating fashion in a multi-step method. In addition to layer-by-layer deposition, other well known nanoparticle assembly techniques include, but are not limited to, Langmuir-Blodgett and in situ nanoparticle synthesis within polymer matrices. These techniques allow precise control and rational design of both physical (e.g., thickness, refractive index, optical transparency) and chemical (e.g., functionality, surface energy) properties.

The as-assembled coating on a substrate can impart desirable optical and wetting properties to the substrate, such as anti-reflective and anti-fogging characteristics. A surface of a transparent object having an anti-fogging coating maintains is its transparency to visible light when compared to the same object without the anti-fogging coating, under conditions that cause water condensation on the surface. Advantageously, an as-assembled coating can be simultaneously anti-fogging and anti-reflective. For example, a porous as-assembled coating can promote infiltration of water droplets into its interstitial void spaces (to prevent fogging); and the interstitial void spaces can also reduce the refractive index of the coating, so that it acts as an anti-reflective coating. The as-assembled coatings can also be self-cleaning. For example, organic contaminants can be removed or oxidized by the coating, e.g., upon exposure to an activation light source such as a UV light source or a visible light source.

Mechanical integrity (e.g., durability and adhesion) of a coating can be important in practical applications. As-assembled coatings such as, for example, TiO₂/SiO₂ nanoparticle-based multilayer coatings can have less than ideal mechanical properties. As is known in the art, the interconnectivity and mechanical robustness of the coatings can be drastically improved by use of a so-called “lock-in” step. The lock-in step can prevent changes in the structure of the porous multilayer and can be achieved by, for example, exposure of the multilayer to thermal or chemical polymerization conditions. The polyelectrolytes can become cross-linked and unable to undergo further transitions in porosity. Thermal polymerization can be achieved by calcinating the as-assembled multilayers at a high temperature (e.g., 550° C.) for a period of time sufficient to fuse the nanoparticles together. This procedure, however, is not suitable for substrates that are unstable at high temperatures, such as plastics. For example, plastics and polymer substrates tend to deform and degrade at high temperatures. A chemical crosslinking step can be preferred when the polyelectrolyte multilayer is formed on a substrate that is unstable at temperatures required for crosslinking (such as, for example, when the substrate is polystyrene). Chemical treatment, however, is not without its downsides as well as it often requires further post-processing steps to wash and remove potentially harmful chemicals from the substrate.

Mechanical stability of the as-assembled thin film coatings can be achieved by depositing a stabilizing coating, by atomic layer deposition (ALD), on the as-assembled coating and within the interstitial void spaces defined by the nanoparticles of the as-assembled coating. Atomic layer deposition (ALD) is a thin film deposition technique that is based on the sequential use of a gas phase chemical process. The majority of ALD reactions use two chemicals, typically called precursors. These precursors react with a surface one-at-a-time in a sequential manner. By exposing the precursors to the growth surface repeatedly, a thin film may be deposited.

ALD is a self-limiting (the amount of film material deposited in each reaction cycle is constant), sequential surface chemistry that deposits conformal atomic-scale thin films of materials onto substrates of varying compositions. By keeping the precursors separate throughout the coating process, atomic layer control of film growth can be obtained as fine as ˜0.1 Angstrom (Å) (i.e., 0.01 nanometers) per monolayer. ALD can be used to deposit several types of thin films, including various oxides (e.g., Al₂O₃, TiO₂, SnO₂, ZnO, HfO₂), metal nitrides (e.g., TiN, TaN, WN, NbN), metals (e.g., Ru, Ir, Pt), and metal sulfides (e.g., CsS, ZnS). Depositing the stabilization coating by atomic layer deposition (ALD) after an as-assembled coating has been applied to a substrate allows the stabilization coating to spread over the as-assembled coating and penetrate within the interstitial void spaces defined by the as-assembled coating.

Various additional treatment steps may be performed before, during, or after the process steps described above. For example, an initial coating may be applied directly to the substrate by atomic layer deposition. For particular substrates such as, for example, plastics, the initial ALD coating has been found to improve the adhesion characteristics of the substrate and enable better coverage by the as-assembled coating. Improved deposition of the as-assembled coating on the substrate may produce more uniformly coated thin films and facilitate better optical, wetting, and mechanical properties of the thin film coated substrate.

Additionally, one or more functional coatings may be applied by atomic layer deposition over the, and within the interstitial void spaces of, the as-assembled coating. These functional coatings may be part of, or in addition to, the stabilization coating applied by atomic layer deposition. Such functional coatings may contain elements which impart, for example, catalytic, optical, absorptive, semiconducting, abrasion-resistive, or corrosion-resistive functionality to the functional coatings. Examples of catalytically functional coatings include oxides and platinum group metals (PGMs), while examples of absorptive functional coatings include oxides and silicas. Various oxides may similarly impart optical functionality to the functional coating, including aluminum oxide, titanium oxide, and hafnium oxide. Semi-conducting functionality can be attained by use of semi-conducting materials such as, for example, cadmium selenide, zinc telluride, and copper sulfide. Known abrasion-resistant materials, such as tungsten sulfide, and corrosion-resistant materials, such as zinc oxide, may also impart specific functionality to the one or more functional coatings. The functional coatings may be combined to achieve the desired performance parameters of the mechanically stable thin film coating. As stated above, the stabilization coating itself may include functional materials which impart specific functionality to the coating such that the stabilization coating and functional materials to the first coating simultaneously.

As described above, additional treatment steps can be performed to improve the mechanical robustness and/or the optical and wetting properties of the thin film coating. For example, the nanoparticle thin film coated substrate may be heated at a temperature sufficient to promote interconnectivity of the materials and improve the mechanical durability of the coating. The nanoparticle thin film coating and substrate may be heated at a temperature of about 100° C. to about 550° C., or preferably from about 100° C. to about 300° C. Similarly, the nanoparticle thin film coated substrate may be treated by plasma treatment or ozone treatment to improve the optical and wetting characteristics of the thin film coating. Plasma treatment or ozone treatment of the substrate may occur during the step of depositing the stabilization coating, in a process known as “plasma-enhanced” or “ozone-enhanced” atomic layer deposition. Alternatively, the nanoparticle thin film coated substrate may be treated by plasma treatment or ozone treatment after the step of depositing the stabilization coating. These additional treatment steps can be combined to achieve the desired mechanical, optical, and wetting properties of the nanoparticle thin film coated substrate, as is known in the art.

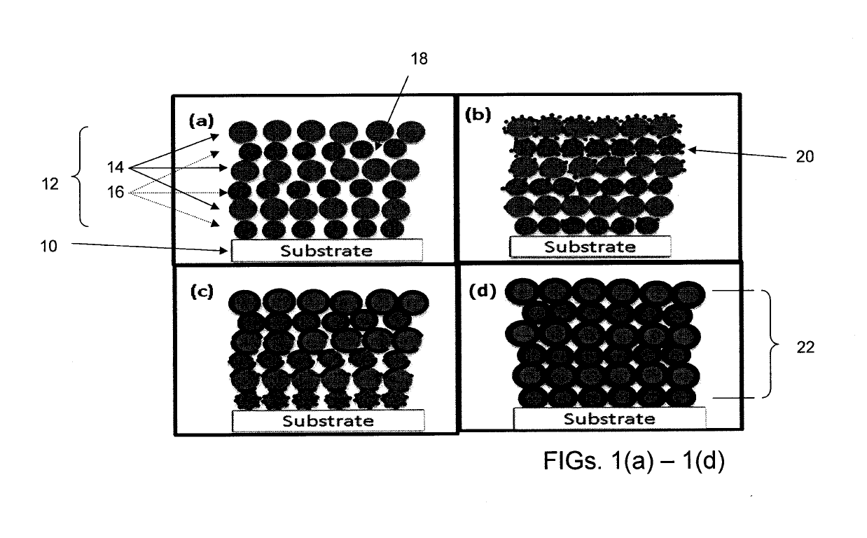

FIGS. 1(a)-1(d) diagram a mechanically stable nanoparticle thin film coating 22 as it is applied to a substrate 10. FIG. 1(a) diagrams the deposition of an as-assembled coating 12 on the substrate 10, and shows a first (i.e., as-assembled) coating 12 which includes a polymer 16 and a plurality of nanoparticles 14. This deposition can be achieved by, for example, layer-by-layer deposition. The as-assembled coating 12 may contain only a plurality of nanoparticles 14. Alternatively, the as-assembled coating may include a polymer 16 and a plurality of nanoparticles 14. As shown, the components of the as-assembled coating define interstitial void spaces 18. FIGS. 1(b) and 1(c) diagram the deposition of a stabilization coating 20 by atomic layer deposition. The stabilization coating deposits atomic-scale material over the as-assembled coating 12 and into the interstitial void spaces 18 defined by the as-assembled coating. In an ALD process that utilizes aluminum oxide (Al₂O₃), the stabilization coating is formed by two precursor gases—water vapor (gaseous H₂O) and trimethylaluminum ((CH₃)₃Al). The aluminum oxide penetrates the interstitial void spaces and substantially coats the components of the as-assembled coating, as diagrammed in FIG. 1(d).

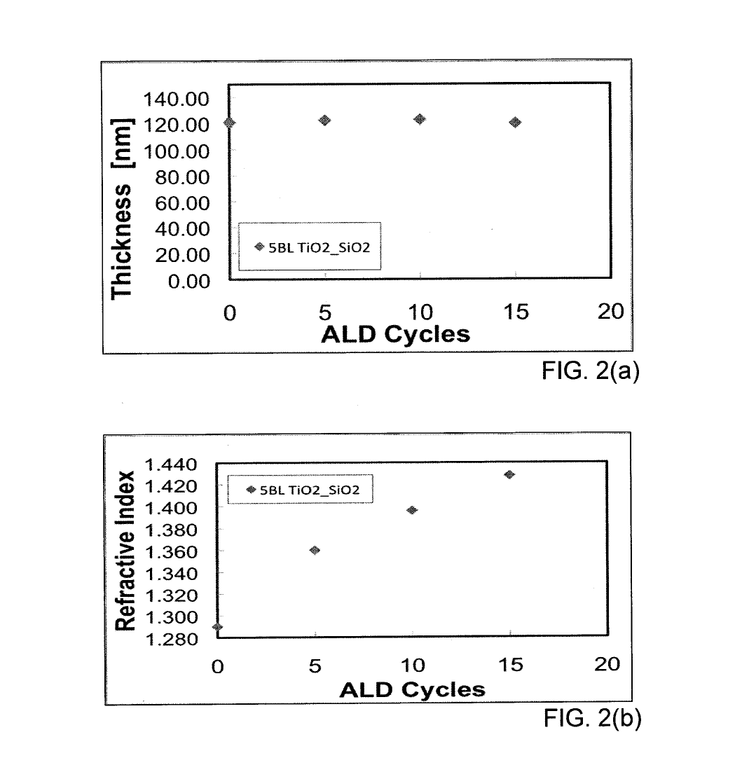

As diagrammed in FIGS. 1(a)-1(d), the stabilization coating does not substantially add to the thickness of the as-assembled thin film coating. This is due to the penetration of the stabilization coating into the interstitial void spaces defined by the as-assembled coating. The as-assembled coating becomes less porous as a result of the stabilization coating, which also increases its refractive index. These characteristics are shown in FIGS. 2(a)-2(b), which details the film thickness and refractive index as measured by spectroscopic ellipsometry.

### EXAMPLES

An all-nanoparticle multilayer of positively charged TiO₂ nanoparticles (average size ˜7 nm) and negatively charged SiO₂ nanoparticles (average size ˜22 nm) was prepared by layer-by-layer assembly using glass as the substrate. Each nanoparticle suspension had a concentration of 0.03 wt. % and a pH of 3.0. The growth behavior of multilayers made of TiO₂ and SiO₂ nanoparticles was monitored using spectroscopic ellipsometry. FIG. 2(a) shows the variation of film thickness with increasing number of atomic layer depositions cycles over a number of deposited as-assembled bilayers (one bilayer consists of a sequential pair of TiO₂ and SiO₂ nanoparticle depositions). Five bilayers of TiO₂ and SiO₂ were deposited on the glass substrates as the as-assembled coating for these tests.

Thickness and refractive index were measured using a Woollam Co. VASE spectroscopic ellipsometer. The data analysis was done using the WVASE32 software package. Measurements were performed using 250 to 900 nm light at a 70° angle of incidence. Measurements were fit to a Cauchy model, a well-known method for spectroscopic ellipsometry and reflectometry, which assumes that the real part of refractive index (n_{f}) can be modeled as shown by Formula 1:

$${n}_{f} ( λ ) = {A}_{n} + \frac{{B}_{n}}{{λ}^{2}} + \frac{{C}_{n}}{{λ}^{4}} , \qquad Formula 1$$

where Aₙ, Bₙ, and Cₙ are constants and λ is the wavelength of incident light. Cn was set to 0 and the refractive index values were determined at 633 nm. Uncoated substrates were first scanned and their properties were saved. It was necessary to roughen the back sides of transparent substrates in order to eliminate reflections from the transmittance side and to collect reflections only from the incidence side. A stack of two Cauchy layers was used to model coated slides. As shown in FIG. 2(a), the nanoparticle thin film coating thickness is about 120 nm. The film coating thickness is not substantially changed by increasing the number of stabilization coatings over, and within the interstitial void spaces of, the as-assembled coating.

The refractive index of the thin film coated substrate was found to have been influenced by repeated atomic layer deposition cycles. As described above, the assembly of nanoparticles results in the presence of nanopores (i.e. interstitial void spaces) which effectively lower the refractive index of the as-assembled multilayer coatings. The five bilayers of TiO₂ and SiO₂ deposited on the glass substrate as the as-assembled coating had a refractive index of about 1.28. As shown in FIG. 2(b), spectroscopic ellipsometry measurements showed an increase in the refractive index as a function of increasing atomic layer deposition cycles of aluminum oxide (Al₂O3). At five cycles of atomic layer deposition, the refractive index had increased to about 1.36. At ten cycles, the refractive index had increased to about 1.395. At fifteen cycles, a refractive index of about 1.425 was identified by spectroscopic ellipsometry. The as-assembled coating becomes less porous as a result of increasing stabilization coatings and, accordingly, has an effect on the anti-reflective characteristic of the coated substrate. Accordingly, the number of ALD cycles for deposition of the stabilization coating can be controlled to achieve suitable mechanical robustness with desirable optical and wetting properties.

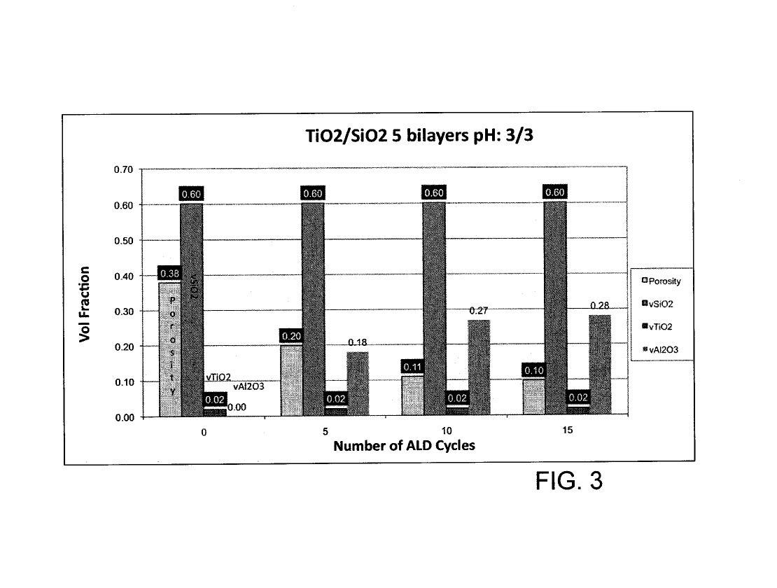

The refractive index and porosity of the thin film coated substrate also relate to the volume fraction of the samples, which is also measured using ellipsometry. FIG. 3 shows the change in volume fraction from the unstabilized as-assembled coating to the mechanically stable thin film coating with fifteen cycles of aluminum oxide deposition by ALD. The porosity is defined by the amount of volume measured as air. The porosity of the thin film coating is decreased as successive cycles of aluminum oxide are deposited by ALD over, and within the interstitial void spaces of, the as-assembled TiO₂/SiO₂ nanoparticle multilayer coating. As discussed above, the as-assembled coating on a substrate can impart desirable optical and wetting properties to the substrate, such as anti-reflective characteristics.

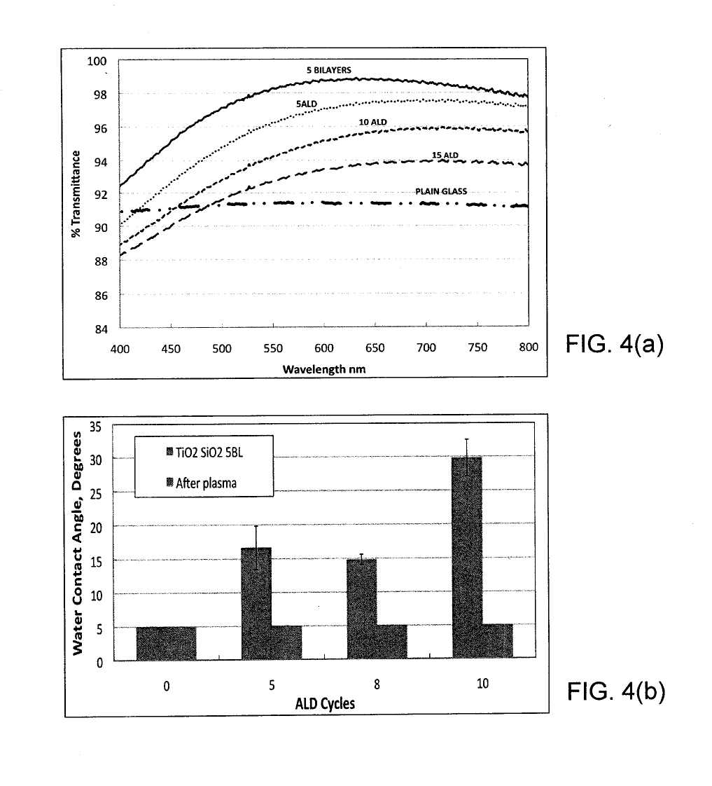

The porosity and interstitial void spaces also relate to the material density of the nanoparticle thin film coating. Depositing the nanoporous as-assembled TiO₂/SiO₂ nanoparticle thin film coatings on glass caused the reflective losses in the visible region to be significantly reduced and transmission levels above 99% to be readily achieved, as measured by UV/Visible spectrophotometry. The wavelength of maximum suppression of reflections in the visible region was determined by the quarter-wave optical thickness of the coatings, which can be varied by changing the number of coatings deposited as seen in FIG. 4(a). A Cary 5E UV-Vis-NIR spectrophotometer (Varian, Inc.) was used to record the transmittance spectra. The transmission of the plain glass substrate was measured as about 91%. A five bilayer as-assembled TiO₂/SiO₂ nanoparticle thin film coating was deposited on the substrate and measured as having a transmission of about 99%. As successive cycles of aluminum oxide were deposited by atomic layer deposition, the material density of the mechanically stable thin film coating increased and the transmission decreased.

The porosity of the as-assembled coating can promote infiltration of water droplets into its interstitial void spaces (to prevent fogging); and the interstitial void spaces can also reduce the refractive index of the coating, so that it acts as an anti-reflective coating. Successive deposition of a stabilization coating into the interstitial void spaces can increase the density of the mechanically stable coating and effect the percent of transmission of the coated substrate. These parameters can be balanced with the amount of stabilization coating deposited by ALD to achieve mechanical robustness, to reach the desired properties of the thin film coating.

In addition to the anti-reflective properties, the nanoporosity of the as-assembled TiO₂/SiO₂ nanoparticle multilayer coating led to superhydrophilicity. Nanoporous coatings which include SiO₂nanoparticles are known to exhibit “superhydrophilicity” (i.e., water droplet contact angle <5 degrees in less than 0.5 seconds) due to the nanowicking of water into the network of capillaries present in the coatings (see U.S. Patent Application Pub. No. 2007/0104922, and Cebeci, F. C.; et al., Langmuir 2006, 22, 2856-2862, each of which is incorporated by reference in its entirety). The mechanism of such behavior can be understood from the simple relation derived by Wenzel and co-workers. It is well established that the apparent contact angle of a liquid on a surface depends on the roughness of the surface according to the following relation:

cos θₐ=r cos θ Formula 2,

where θa is the apparent water contact angle on a rough surface and θ is the intrinsic contact angle as measured on a smooth surface. r is the surface roughness defined as the ratio of the actual surface area over the project surface area. r becomes infinite for porous materials meaning that the surface will be completely wetted (i.e., θₐ˜0) with any liquid that has a contact angle (as measured on a smooth surface) of less than 90°. The contact angle of water on a planar SiO₂ and TiO₂ surface is reported to be approximately 20° and 50˜70°, respectively; therefore, multilayers comprised of SiO₂ nanoparticles (majority component) and TiO₂ nanoparticles (minority component) with nanoporous structures should exhibit superhydrophilicity. This is confirmed by the data shown in FIG. 4(b), which shows the change in contact angle of a water droplet with increasing ALD cycles of aluminum oxide on a five bilayer as-assembled TiO₂/SiO₂ nanoparticle multilayer coating.

A drop of water (1.5 μL) was deposited on a sample surface using a Ramehart Instrument goniometer. A DROP Image Advanced image analysis program was used to calculate the contact angle of the drop. Several samples were used in each instance and the averages were taken. As detailed in FIG. 4(b), the as-assembled TiO₂/SiO₂ nanoparticle multilayer coating had a water droplet contact angle of 5 degrees. The water droplet contact angle increased, generally, as more aluminum oxide stabilization coating was deposited by successive cycles of ALD. At 5 cycles of ALD the water contact angle increased to about 16 degrees, while at 10 cycles of ALD the water contact angle increased to about 30 degrees. The mechanically stable thin film coated samples remained in the range defined in the industry as “hydrophilic” (i.e., water droplet contact angle <80 degrees). FIG. 4(b) also shows that the water droplet contact angle, and the superhydrophilicity of the coating, can be retained by plasma treatment of the coating. As described above, plasma treatment of the coating can occur simultaneous with the deposition of the stabilization coating by ALD, in a process known as “plasma-enhanced” atomic layer deposition. Alternatively, plasma treatment can occur as a subsequent step after ALD. Notably, the water contact angle for these plasma treatment samples remained at 5 degrees, qualifying the nanoparticle thin film coating as superhydrophilic. In fact, the water droplet contact angle may be less than 5 degrees in some cases. However, a water droplet contact angle below 5 degrees is generally immeasurable and, accordingly, is nominally assigned a value of 5 degrees. The superhydrophilicity of the coating is a measure of its anti-fogging properties.

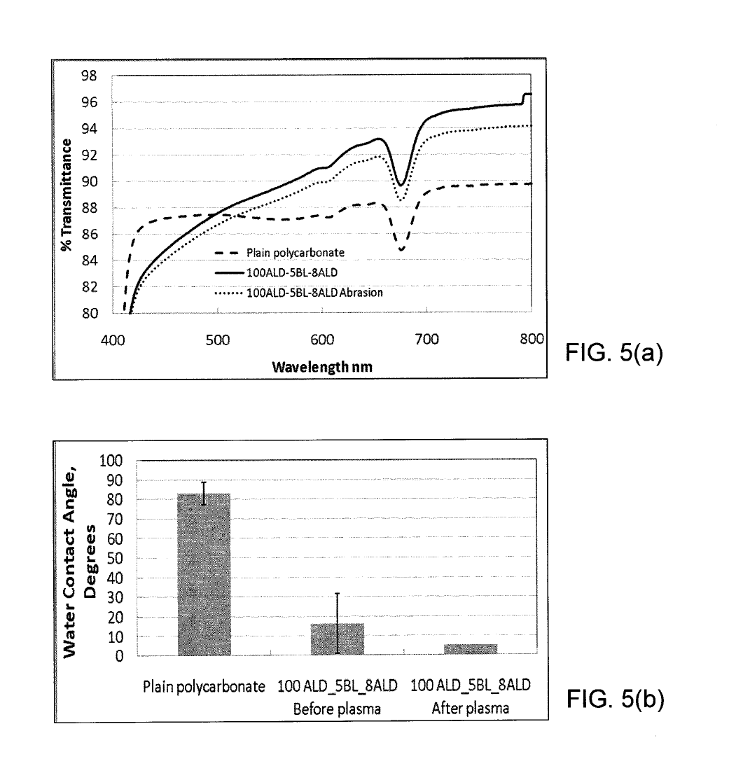

As described above, an initial coating may be deposited by atomic layer deposition before the application of an as-assembled coating for particular substrates, such as polycarbonates. It has now been found that such initial ALD coatings improve the adhesion of the as-assembled nanoparticle thin film coating to the substrate. The improved adhesion of the as-assembled nanoparticle thin film coating to the substrate is shown in the increased superhydrophilicity and improved water droplet contact angle of the coating, as shown in FIG. 5(b). FIGS. 5(a) and 5(b) show the transmission and the water droplet contact angle measurements, respectively, for a coated polycarbonate substrate. The polycarbonate substrate was initially coated with 100 deposition cycles by ALD. A five bilayer as-assembled TiO₂/SiO₂ nanoparticle multilayer coating was then deposited, followed by eight cycles of a stabilization coating deposited by ALD.

FIG. 5(a) shows that this process utilizing an initial coating by ALD on the substrate improved the anti-reflective properties of the mechanically stable nanoparticle thin film coating, when compared to the plain polycarbonate substrate. FIG. 5(b) shows that the water droplet contact angle of the polycarbonate substrate was improved by application of the mechanically stable thin film coating, including an initial adhesion layer applied to the substrate by ALD. The water droplet contact angle of the plain polycarbonate substrate was about 83 degrees, while the water droplet contact angle decreased to about 16 degrees after application of the mechanically stable thin film coating. Accordingly, the hydrophilicity of the substrate is improved by application of the mechanically stable thin film coating, including an initial adhesion layer applied to the polycarbonate substrate by ALD. FIG. 5(b) also shows that the superhydrophilicity of the coating and the water droplet contact angle can be retained and improved by plasma treatment of the coating. As described above, plasma treatment of the coating can occur simultaneous with the deposition of the stabilization coating by ALD (i.e., “plasma-enhanced” atomic layer deposition), or plasma treatment can occur as a subsequent step after ALD. In fact, the substrate is made superhydrophilic by the coatings and plasma treatment, which aids in achieving the desirable optical and wetting properties described above.

For practical application of any coating, the mechanical integrity (durability and adhesion) can be extremely important. As-assembled TiO₂/SiO₂ nanoparticle multilayer coatings show less than ideal mechanical properties. Without being held to any theory, the poor adhesion and durability of the as-assembled multilayer coatings may be due to the absence of any interpenetrating components (i.e., charged macromolecules) that bridge or glue the deposited particles together within the multilayers. The mechanical properties of the nanoparticle multilayers can be improved significantly by calcinating the as-assembled multilayers at a high temperature (550° C.), but this process is not suitable for certain substrates that deform and degrade at elevated temperatures. Earlier analysis of the high temperature calcination product showed that the film thickness decreased by about 5% and the refractive index increased slightly (about 2%) after the calcination process. (see Cebeci, F. C.; et al., Langmuir 2006, 22, 2856-2862, which is incorporated by reference in its entirety). It is important to impart mechanical robustness to nanoparticle thin film coatings, while also retaining or improving their desirable optical and wetting properties, by a process that may be employed for all substrates.

The process of the present invention imparts mechanical stability and robustness to nanoparticle thin film coatings, akin to that achieved by high temperature calcination, and can be utilized for a variety of substrates because it does not require heat treatment at high temperature. The mechanical stability and robustness of the present invention relate to the hardness, tensile modulus (i.e., Young's modulus), adhesion, and abrasion resistance characteristics of the coating, which are improved when compared to the characteristics of an as-assembled nanoparticle thin film coating. The mechanical robustness of the samples was determined by the difference in the transmission measurements before and after the samples were abraded. The quantitative abrasion test was adapted from the Taber abrasion test (ASTM D 1044) and the Cleaning Cloth Abrasion Test of Colts Laboratories. The cleaning cloth abrasion test by Colts Laboratories involves rubbing a lens with a soft cloth for 4000 cycles, where one cycle consists of one back-and-forth motion. The motion range of the testing instrument (i.e., the distance traveled by the cloth in each back or forth motion) is ˜0.5 in. Accordingly, the total path length the cloth travels on the lens is ˜100 m. The lens diameter is 4.5 cm, and 10 lb (44.5 N) force is applied. Thus, the normal stress is ˜28 kPa.

The abrasion testing was performed using a Struers Rotopol 1 polishing machine equipped with a Pedemat automatic specimen mover, operated at 150 rpm against a dry Struers DP-NAP polishing cloth. The Pedemat specimen mover can apply a minimum of 30 N force in the single sample mode. Therefore, the polishing cloth was cut into 2 cm circles to achieve approximately 100 kPa normal stress. Since the samples were abraded with rotational motion, the edges of the samples travel the longest distance while the centers of the samples should—in theory—remain stationary. The spectrophotometer beam spot is an 8 mm-long, thin line. Therefore, if the beam is aligned at the center of an abraded sample, the measured transmittance samples the film from the center to a 4 mm radius. Approximately 15 minutes of testing were necessary using 100 kPa normal stress. All samples were gently washed with a cellulose sponge soaked in an approximately 2% laboratory glassware detergent solution before and after abrasion testing. The washing step is critical, as contaminants from the cloth infiltrate the porous coatings and increase their refractive indices. The transmission levels were then measured by UV/Visible spectrophotometry, as described above.

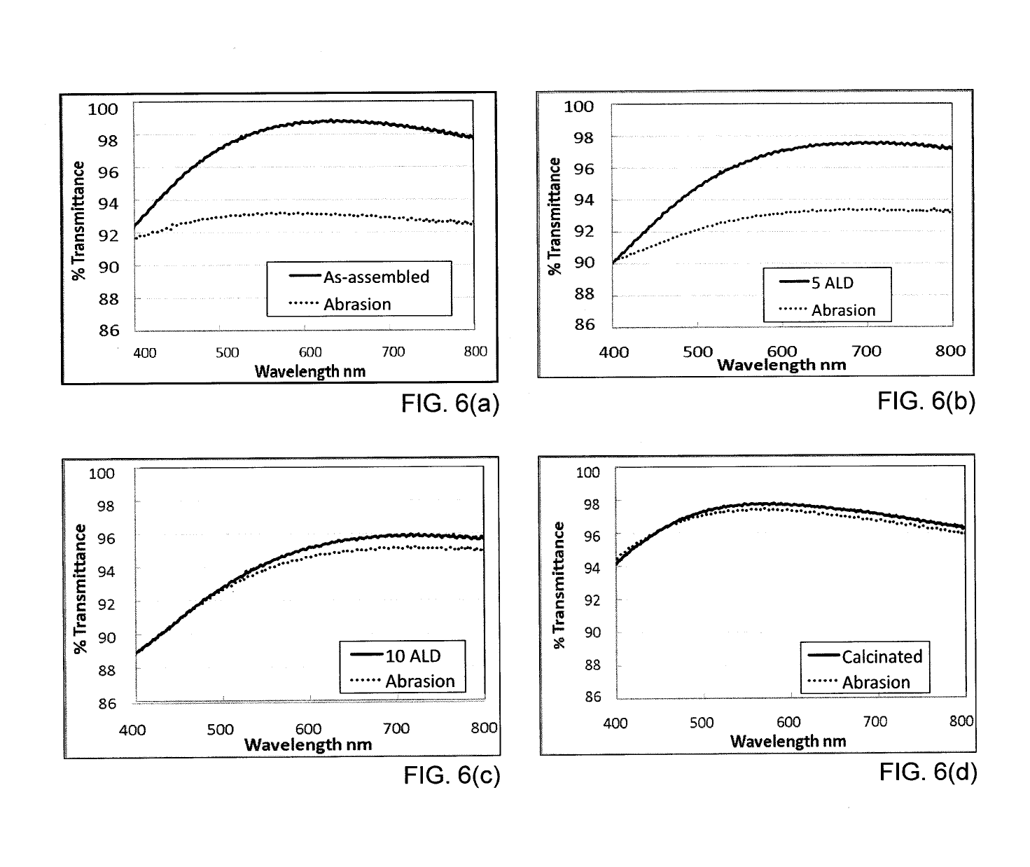

FIGS. 6(a)-6(d) present the transmission levels measured by UV/Visible spectrophotometry for various coatings applied to glass substrates. FIG. 6(a) compares the transmission level of the as-assembled TiO₂/SiO₂ nanoparticle multilayer coating on the glass substrate before and after it has been abraded. The transmission level is reduced from about 99% to about 93% after abrasion. FIG. 6(a) shows that this coating lacks mechanical robustness as the abrasion testing resulted in a substantial loss in the anti-reflective property imparted by the as-assembled nanoparticle coating in this sample. FIGS. 6(b) and 6(c) compare the transmission levels of the nanoparticle thin films coated by 5 and 10 cycles of the aluminum oxide stabilization coating, respectively, before and after these samples have been abraded. As can be seen by the figures, the mechanical robustness (i.e., the retention of the transmission levels before and after abrasion testing) is improved as additional ALD cycles are applied. FIGS. 6(c) shows that the mechanically stable nanoparticle thin film coatings, which were produced without thermal calcination, have comparable transmission levels in the pre- and post-abraded samples. In fact, FIG. 6(c) shows pre- and post-abraded samples that are akin to the calcinated sample shown in FIG. 6(d). Accordingly, the process of the present invention imparts mechanical stability and robustness to nanoparticle thin film coatings, substantially equivalent to that achieved by high temperature calcination, and can be utilized for a variety of substrates as it does not require heat treatment at high temperature.

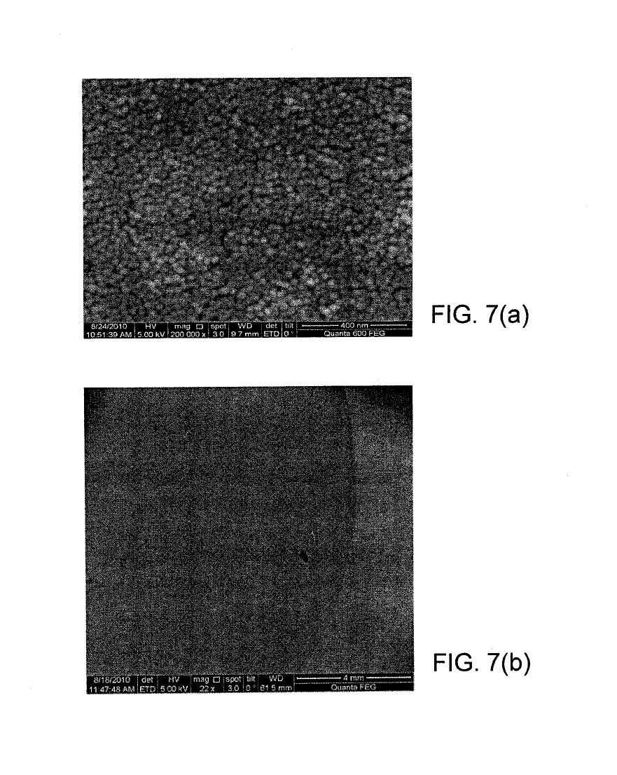

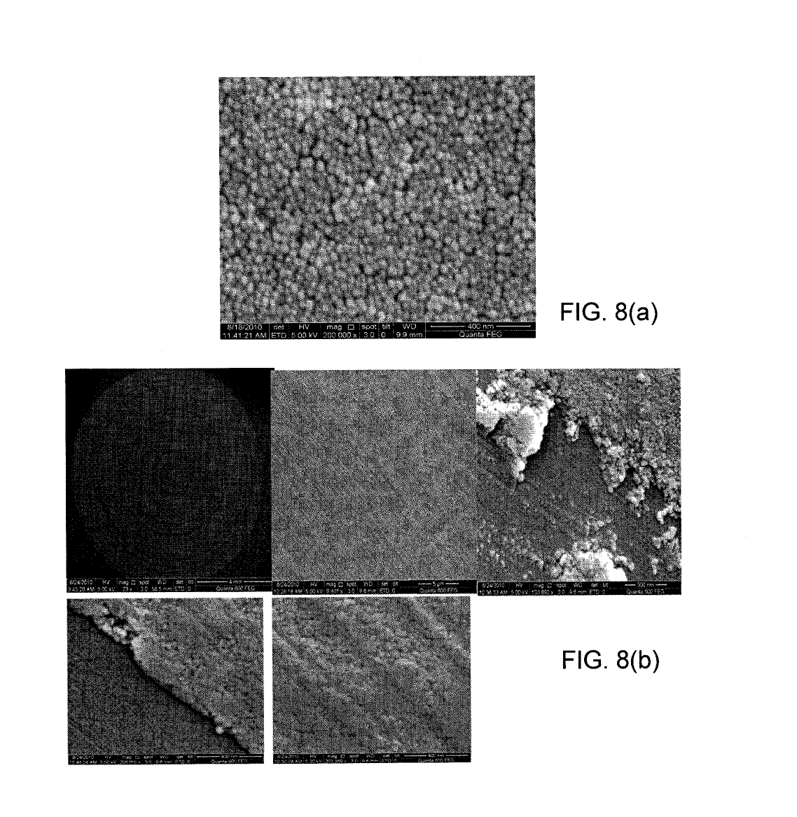

Micrograph images of the coated substrates as seen by Scanning Electron Microscopy (SEM), before and after abrasion testing, confirm the mechanical robustness imparted by the process of the present invention. A JEOL SEM was used in high-vacuum mode for the imaging. FIGS. 7(a) and 7(b) provide SEM images of a five bilayer as-assembled TiO₂/SiO₂ nanoparticle thin film coating deposited on a glass substrate, before and after abrasion testing, respectively. As can be seen in FIG. 7(b), a clear trace line marks the edge of the abrasion path and shows that all the nanoparticles of the thin film coating were abrated. This shows poor mechanical robustness of the as-assembled TiO₂/SiO₂ nanoparticle thin film coating. FIGS. 8(a) and 8(b) provide SEM images of a five bilayer as-assembled TiO₂/SiO₂ nanoparticle thin film coating deposited on a glass substrate, modified by 10 cycles of a stabilization coating deposited by atomic layer deposition, before and after abrasion testing, respectively. FIG. 8(a), when compared with FIG. 7(a), shows no apparent visual change as a result of the stabilization coating deposited by ALD. This comports with the explanation of the stabilization coating provided above, namely that the stabilization coating deposited by ALD is applied over the, and within the interstitial void spaces of, the as-assembled coating. FIG. 8(b), however, shows that post-abrasion testing the mechanically stable nanoparticle thin film coating is scratched but has retained the nanoparticle coating. The SEM images shown in FIG. 8(b) are at varying magnification. The retention of the nanoparticle coating is indicative of the improved mechanical robustness imparted by the stabilization coating deposited by atomic layer deposition.

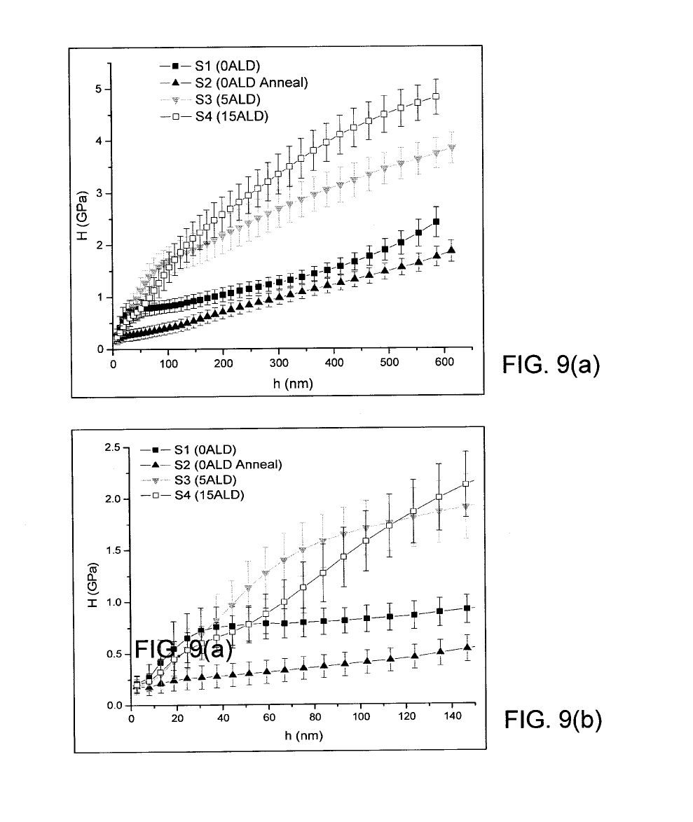

The mechanical robustness of the thin film coatings was also determined by nanoindentation. Nanoindentation experiments were performed using an Agilent NanoIndenter G200 (Agilent Technologies, Santa Clara, Calif.). The system was fitted with a Berkovich indenter (three-sided pyramid shape tip). Analysis of the samples was made according to well known techniques to one having ordinary skill in the art. (see Oliver, W. C.; et al. Improved technique for determining hardness and elastic modulus using load and displacement sensing indentation experiments. J. Mater. Res. 1992, 7 (6), 1564-1583, and Mott, B. W. Microindentation Hardness Testing. Butterworths: London, UK, 1956, 9 pp., both of which are incorporated by reference in their entirety). The mechanically stable nanoparticle thin film coatings were applied to glass substrates, for which the Meyer's hardness was measured and the Young's modulus of elasticity calculated. FIGS. 9(a) and 9(b) present the hardness measurements, charting displacement h in nanometers (nm) and hardness H in gigapascals (GPa). Displacement of the samples was performed from 0 to 620 nm. However, the thickness of the mechanically stable nanoparticle thin film coating was about 400 nm. Measurements above 400 nm relate to displacement of the glass substrate, not the thin film coating. Accordingly, only displacement measurements from 0 to 400 nm are relevant for this analysis and are discussed below. The as-assembled nanoparticle thin film coating had a hardness range from about 0.2 to about 1.5 GPa. The hardness of this coating was reduced, by annealing the as-assembled nanoparticle coating, to a range of about 0.2 to about 1.2 GPa. As seen in the figures, the hardness of the samples was substantially improved by deposition of the stabilization coating by ALD. 5 cycles of ALD of the stabilization coating improved the hardness measurements to a range of about 0.2 to about 3.0 GPa. 15 cycles of ALD of the stabilization coating improved the hardness measurements further, to a range of about 0.2 to about 4.0 GPa. As the number of ALD cycles increased, the hardness of the samples improved. These results can be seen in FIG. 9(a). FIG. 9(b) shows a magnified view of these results for the displacement range between 0 to 150 nm.

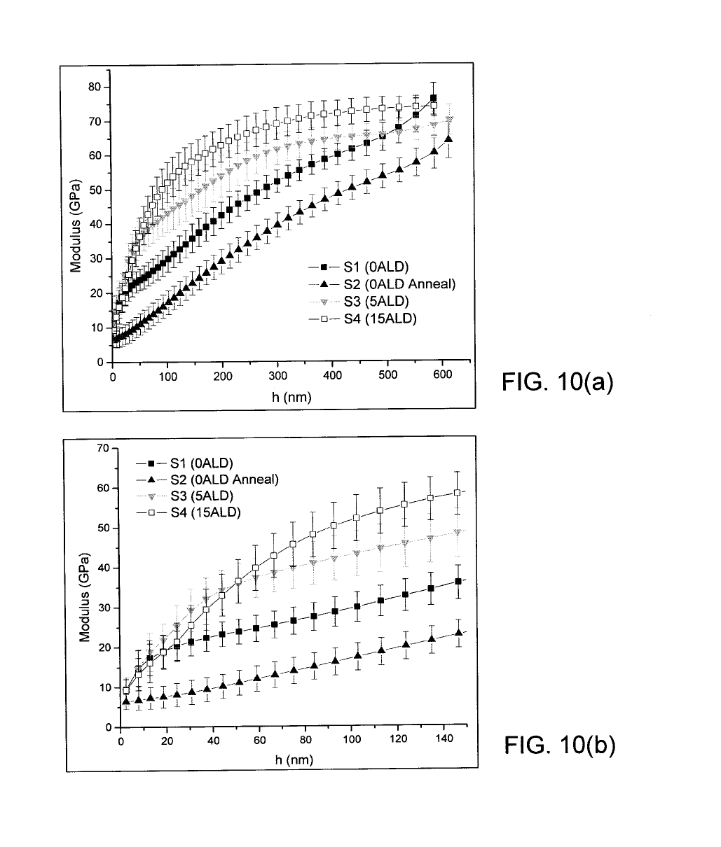

FIGS. 10(a) and 10(b) show the calculated modulus measurements in graphical form. Again, displacement of the samples was performed from 0 to 620 nm. As with the hardness measurements, however, the thickness of the mechanically stable nanoparticle thin film coating was about 400 nm and only displacement measurements from 0 to 400 nm are relevant for this analysis. The as-assembled nanoparticle thin film coating had a calculated modulus range from about 10 to about 60 GPa. Similar to the hardness measurements, annealing the as-assembled nanoparticle coating reduced the modulus to a range of about 6 to about 48 GPa. The modulus of the samples was substantially improved by deposition of the stabilization coating by ALD. 5 cycles of ALD of the stabilization coating improved the modulus calculations to a range of about 10 to about 65 GPa. 15 cycles of ALD of the stabilization coating improved the modulus calculations further, to a range of about 10 to about 72. As was seen for the hardness measurements, the modulus of the samples improved with increased number of ALD cycles. These results can be seen in FIG. 10(a). FIG. 10(b) shows a magnified view of these results for the displacement range between 0 to 150 nm.

As seen from the examples and figures, the mechanically stable thin film coatings of the present invention are superhydrophilic and improve the mechanical robustness of the nanoparticle thin film, while retaining or improving the desirable optical and wetting properties of the thin film coating. The methods of the present invention for treating a surface, which utilize atomic layer deposition (ALD) to deposit a stabilization coating over, and within the interstitial void spaces of, the as-assembled nanoparticle thin film coating, impart desirable optical, wetting, and mechanical characteristics to the nanoparticle thin film and can be employed on a myriad of substrates.

Although the invention is illustrated and described herein with reference to specific embodiments, the invention is not intended to be limited to the details shown. Rather, various modifications may be made in the details within the scope and range of equivalents of the claims and without departing from the invention.

1. A method for treating a surface comprising the steps of:
depositing a first coating comprising a plurality of nanoparticles on a substrate, wherein the first coating defines a plurality of interstitial spaces; and
depositing a second coating comprising metals, metal oxides, or mixtures thereof by atomic layer deposition (ALD) on the first coating and within the interstitial spaces defined by the first coating.

2. The method of claim 1, wherein the first coating comprises the plurality of nanoparticles and a polymer, and the plurality of nanoparticles and the polymer are in the form of a film.

3. The method of claim 1, further comprising, after depositing the second coating, the step of:
depositing one or more functional coatings by atomic layer deposition.

4. The method of claim 3, wherein the one or more functional coatings contain elements which impart catalytic, optical, absorptive, semiconducting, abrasion-resistive, or corrosion-resistive functionality to the functional coatings.

5. The method of claim 1, further comprising, after or during the step of depositing the second coating, the step of:
treating by plasma treatment or ozone treatment.

6. The method of claim 1, further comprising, after the step of depositing the second coating, the step of:
heating the substrate to a temperature of about 100° C. to about 300° C.

7. The method of claim 1, wherein the plurality of nanoparticles are deposited on the substrate by spin-coating, dip-coating, solution-coating, doctor blading, or spray-coating.

8. The method of claim 1, wherein the plurality of nanoparticles are selected from the group consisting of silicon dioxide nanoparticles, titanium dioxide nanoparticles, and mixtures thereof.

9. The method of claim 1, wherein the second coating is a coating of metal oxides selected from the group consisting of aluminum oxide (Al₂O₃), silicon oxide (SiO₂), and titanium oxide (TiO₂), and mixtures thereof.

10. A process for producing a mechanically stable coating on a surface, the process comprising the steps of:
depositing an adhesion layer comprising metals, metal oxides, or mixtures thereof by atomic layer deposition (ALD) on a substrate;
depositing a first coating comprising a plurality of nanoparticles on the adhesion layer, wherein the first coating defines a plurality of interstitial spaces; and
depositing a second coating comprising metals, metal oxides, or mixtures thereof by atomic layer deposition (ALD) on the first coating and within the interstitial spaces defined by the first coating.

11. The process of claim 10, wherein the first coating comprises the plurality of nanoparticles and a polymer, and the plurality of nanoparticles and the polymer are in the form of a film.

12. The process of claim 10, further comprising, after depositing the second coating, the step of:
depositing one or more functional coatings by atomic layer deposition.

13. The process of claim 10, further comprising, after or during the step of depositing the second coating, the step of:
treating by plasma treatment or ozone treatment.

14. The process of claim 10, further comprising, after the step of depositing the second coating, the step of:
heating the substrate to a temperature of about 100° C. to about 300° C.

15. A mechanically stable coated product comprising
a substrate;
a first coating comprising a plurality of nanoparticles deposited on the substrate;
wherein the first coating defines a plurality of interstitial spaces; and
a second coating comprising metals, metal oxides, or mixtures thereof deposited by atomic layer deposition (ALD) on the first coating and within the interstitial spaces defined by the first coating.

16. The mechanically stable coated product of claim 15, further comprising one or more functional coatings deposited by atomic layer deposition.

17. The mechanically stable coated product of claim 15, wherein the plurality of nanoparticles are selected from the group consisting of silicon dioxide nanoparticles, titanium dioxide nanoparticles, and mixtures thereof.

18. The mechanically stable coated product of claim 15, wherein the second coating is a coating of metal oxides selected from the group consisting of aluminum oxide (Al₂O₃), silicon oxide (SiO₂), and titanium oxide (TiO₂), and mixtures thereof.

19. The mechanically stable coated product of claim 15, wherein the second coating is deposited at a thickness of about 0.01 nanometers to about 100 nanometers.

20. The mechanically stable coated product of claim 15, wherein the first coating and the second coating are deposited at a total thickness of about 0.01 nanometers to about 100 microns.
